(19) United States
(12) Patent Application Publication
(10) Pub. No.: US 2014/0201547 A1
(43) Pub. Date: Jul. 17, 2014

(54) Selective Precharge for Power Savings

(71) Applicant: APPLE INC., Cupertino, CA (US)

(72) Inventors: Abhijeet R. Tanpure, Austin, TX (US); Alexander E. Runas, Austin, TX (US)

(73) Assignee: Apple Inc., Cupertino, CA (US)

(21) Appl. No.: 13/741,443

(22) Filed: Jan. 15, 2013

(51) Int. Cl. G06F 1/32; G11C 7/22

(52) U.S. Cl. CPC G06F 1/3275; G11C 7/22
USPC 713/320; 711/167

(57) ABSTRACT

Embodiments of a memory device are disclosed that may allow for detecting the opportunity for energy savings and implementing the energy savings for each access to the memory device. The memory device may include a plurality of columns, an address comparator, and a timing and control circuit. Each of the plurality of columns may include a plurality of data storage cells coupled to a common data line, and a pre-charge circuit that may be configured to charge the common data line to a pre-determined voltage. The address comparator may be configured to compare an address value to a previous address value, and generate an output dependent upon the comparison. The timing and control circuit may then selectively disable pre-charge circuits in the plurality of columns dependent upon the generated output of the address comparator.

### BACKGROUND

1. Technical Field

This invention is related to the field of integrated circuit implementation, and more particularly to the implementation of memories.

2. Description of the Related Art

Computing systems may include one or more systems on a chip (SoC), which may integrate a number of different functions, such as graphics processing, onto a single integrated circuit. With numerous functions included in a single integrated circuit, chip count may be kept low in mobile computing systems, such as tablets, for example, which may result in a smaller form factor for such mobile computing systems.

Memories, such as those included in SoC designs, typically include a number of data storage cells arranged in an array, and composed of transistors fabricated on a semiconductor substrate. Such data storage cells may be constructed according to a number of different circuit design styles. For example, the data storage cells may be implemented as a single transistor coupled to a capacitor to form a dynamic storage cell. Alternatively, cross-coupled inverters may be employed to form a static storage cell, or a floating gate metal-oxide semiconductor field-effect transistor (MOSFET) may be used to create a non-volatile memory.

During a read or write access to a memory, power may be dissipated through a variety of mechanisms. For example, decoding an address value to select a specific subset of data storage cells may require the activation of static or dynamic decoders that consume power during the decode process. Between repeated accesses to a memory, the data storage array of the memory may need to be initialized or pre-charged, which may also contribute to the power dissipated by the memory.

### SUMMARY OF THE EMBODIMENTS

Various embodiments of a memory circuit are disclosed. Broadly speaking, a circuit and a method are contemplated in which a memory circuit includes a plurality of columns, an address comparator circuit, and a timing and control circuit. Each of the plurality of columns may include a plurality of data storage cells and a pre-charge circuit. The address comparator may compare an address value to a previous address value. The timing and control circuit may disable at least one pre-charge circuit dependent upon the comparison of the address value to the previous address value.

In another embodiment, the timing and control circuit may be configured to receive a memory mode control signal. At least one pre-charge circuit may be disabled, by the timing and control circuit, dependent upon the received memory mode control signal.

In a further embodiment, the address comparator may include a register. The register may store the address value.

### BRIEF DESCRIPTION OF THE DRAWINGS

The following detailed description makes reference to the accompanying drawings, which are now briefly described.

FIG. 1 illustrates an embodiment of a system-on-a-chip.

FIG. 2 illustrates an embodiment of a memory device.

FIG. 3 illustrates an embodiment of a memory sub-array.

FIG. 4 illustrates an embodiment of a pre-charge circuit.

FIG. 5 illustrates an embodiment of an address comparison circuit.

FIG. 6 illustrates a flowchart of an example method for operating a data storage device.

FIG. 7 illustrates a flowchart of an example method for performing repeated operations to a same column within a memory.

FIG. 8 illustrates a flowchart of an example method for performing repeated operations to a same row within a memory.

FIG. 9 illustrates a flowchart of an example method for performing repeated operations to the same address within a memory.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form illustrated, but on the contrary, the intention is to cover all modifications, equivalents and alternatives falling within the spirit and scope of the present disclosure as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component. More generally, the recitation of any element is expressly intended not to invoke 35 U.S.C. §112, paragraph six interpretation for that element unless the language “means for” or “step for” is specifically recited.

### DETAILED DESCRIPTION OF EMBODIMENTS

In computing systems, data to be processed may be stored in memories while waiting to be processed. Some data, such as pixel data used control a display, may be stored with a spatial dependence, i.e., data for adjacent pixels may be stored in adjacent data storage cells, in a memory to allow for easy retrieval during display refresh operations. Other data may have a temporal dependence, such as program instructions for a software program. Data with such dependence may also benefit from being stored with a spatial dependence within a memory.

When retrieving data that was stored in a fashion as described above, the address used the access the memory may be sequentially incremented from one access to the next by a fixed quantity. Under such sequential access patterns, it may be possible to forego one or more of initialization steps typically necessary before accessing a memory. Through the elimination of such initialization steps, reduced energy dissipation and reduced access time of the memory may be possible.

### System-on-a-Chip Overview

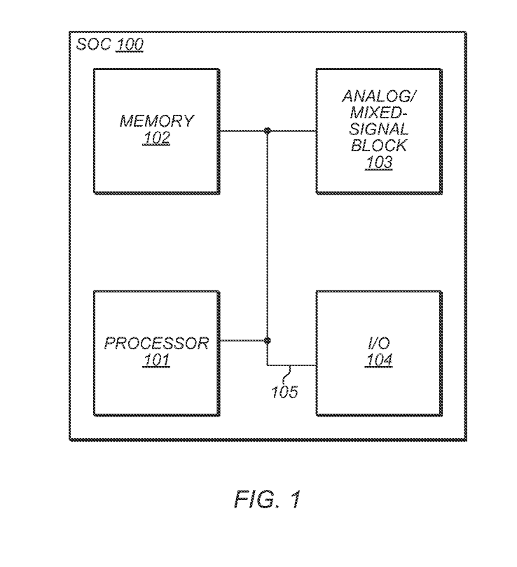

A block diagram of an SoC is illustrated in FIG. 1. In the illustrated embodiment, the SoC 100 includes a processor 101 coupled to memory block 102, and analog/mixed-signal block 103, and I/O block 104 through internal bus 105. In various embodiments, SoC 100 may be configured for use in a mobile computing application such as, e.g., a tablet computer or cellular telephone.

Processor 101 may, in various embodiments, be representative of a general-purpose processor that performs computational operations. For example, processor 101 may be a central processing unit (CPU) such as a microprocessor, a microcontroller, an application-specific integrated circuit (ASIC), or a field-programmable gate array (FPGA). In some embodiments, processor 101 may include one or more register files and memories.

In some embodiments, processor 101 may implement any suitable instruction set architecture (ISA), such as, e.g., the ARM™, PowerPC™, or x86 ISAs, or combination thereof. Processor 101 may include one or more bus transceiver units that allow processor 101 to communication to other functional blocks within SoC 100 such as, memory block 102, for example.

Memory block 102 may include any suitable type of memory such as a Dynamic Random Access Memory (DRAM), a Static Random Access Memory (SRAM), a Read-only Memory (ROM), Electrically Erasable Programmable Read-only Memory (EEPROM), a FLASH memory, or a Ferroelectric Random Access Memory (FeRAM), for example. In some embodiments, memory block 102 may be configured to store program code or program instructions that may be executed by processor 101. Memory block 102 may, in other embodiments, be configured to store data to be processed, such as graphics data, for example.

It is noted that in the embodiment of an SoC illustrated in FIG. 1, a single memory block is depicted. In other embodiments, any suitable number of memory blocks and memory types may be employed.

Analog/mixed-signal block 103 may include a variety of circuits including, for example, a crystal oscillator, a phase-locked loop (PLL) or delay-locked loop (DLL), an analog-to-digital converter (ADC), and a digital-to-analog converter (DAC) (all not shown). In other embodiments, analog/mixed-signal block 103 may be configured to perform power management tasks with the inclusion of on-chip power supplies, voltage regulators, and clock frequency scaling circuitry. Analog/mixed-signal block 103 may also include, in some embodiments, radio frequency (RF) circuits that may be configured for operation with cellular telephone networks.

I/O block 104 may be configured to coordinate data transfer between SoC 101 and one or more peripheral devices. Such peripheral devices may include, without limitation, storage devices (e.g., magnetic or optical media-based storage devices including hard drives, tape drives, CD drives, DVD drives, etc.), audio processing subsystems, graphics processing subsystems, or any other suitable type of peripheral devices. In some embodiments, I/O block 104 may be configured to implement a version of Universal Serial Bus (USB) protocol or IEEE 1394 (Firewire®) protocol, and may allow for program code and/or program instructions to be transferred from a peripheral storage device for execution by processor 101.

I/O block 104 may also be configured to coordinate data transfer between SoC 301 and one or more devices (e.g., other computer systems or SoCs) coupled to SoC 100 via a network. In one embodiment, I/O block 104 may be configured to perform the data processing necessary to implement an Ethernet (IEEE 802.3) networking standard such as Gigabit Ethernet or 10-Gigabit Ethernet, for example, although it is contemplated that any suitable networking standard may be implemented. In some embodiments, I/O block 104 may be configured to implement multiple discrete network interface ports.

It is noted that the SoC illustrated in FIG. 1 is merely an example. In other embodiments, different functional blocks and different configurations of functions blocks may be possible dependent upon the specific application for which the SoC is intended.

### Memory Architecture and Operation

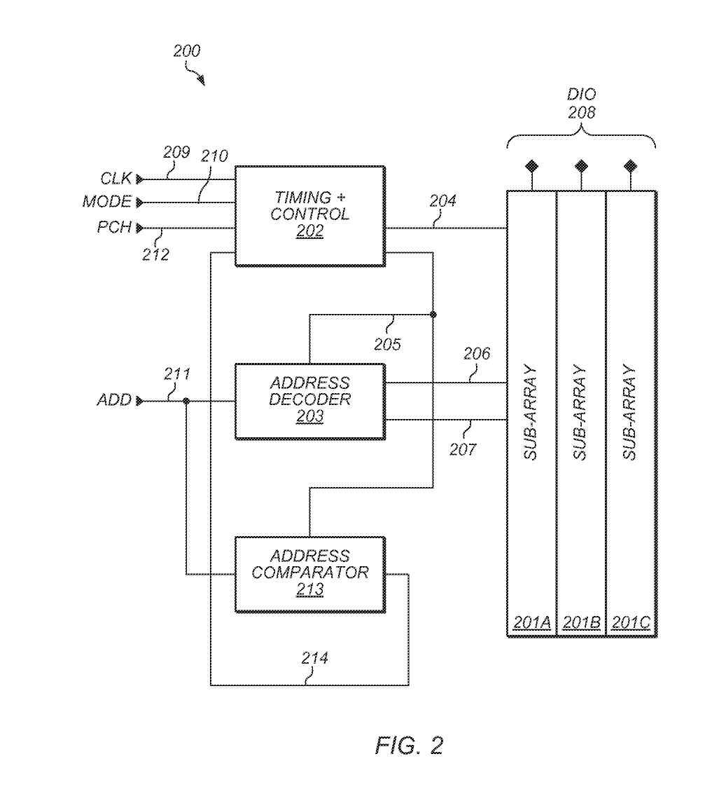

Turning to FIG. 2, a memory is illustrated according to one of several possible embodiments. In some embodiments, memory 200 may correspond to memory block 102 as depicted in FIG. 1. The illustrated embodiment includes data I/O ports 208 denoted as “dio,” an address bus input 211 denoted “add,” mode selection input 210 denoted as “mode,” pre-charge control input 212 denoted as “pch,” and clock input 209 denoted as “clk.”

In the illustrated embodiment, memory 200 includes sub-arrays 201a, 201b, and 201c, timing and control unit 202, address decoder 203, and address comparator 213. Timing and control unit 202 is coupled to provide a decoder enable signal 205 to address decoder 203, and control signals 204 to sub-arrays 201a-201c. In some embodiments, control signals 204 may include a sense amplifier enable signal, an output enable signal, and data input latch signal, and a pre-charge signal. The pre-charge signal may, in other embodiments, be dependent upon an address match signal 214 generated by address comparator 213.

Timing and control block 202 may include a state machine or state logic, and may be configured to provide control signals 204 dependent upon the status of the state machine or state logic as well as clock input 209, mode selection input 210, and pre-charge control input 212. In some embodiments, timing and control block 202 may include a decode circuit to determine the operating mode of memory 200, such as, e.g., a data storage or “write” operation, dependent upon the state of mode selection input 210. In other embodiments, timing and control block 202 may include registers configured to store previous states of mode selection input 210. A comparator configured to compare the state of mode selection input 210 to a previously stored state of mode selection input 210 may be included in timing and control block 202.

In other embodiments, the function performed by timing and control block 202 may be performed external to memory 200 by a processor, such as, e.g., processor 101 of SoC 100 as illustrated in FIG. 1. In such cases, control signals 204 may be directly supplied to memory 200 by processor 101.

Address decoder 203 is coupled to provide row selection signals 206 and column selection signals 207, in response to the assertion of decoder enable signal 205 and dependent upon the address value encoded on address bus input 211. In some embodiments, row decoder 203 may employ a n-to-2ⁿ decoding scheme where n is the number of bits in the address value encoded on address bus input 211, or any suitable decoding scheme, to generate row selection signals 206 and column selection signals 207. The decoding scheme may be employed on a portion of the data bits included in address bus input 211 to generate row selection signals 206. The remaining data bits included in address bus input 211 may be decoded to generated column selection signals 207. Column selection signals 207 may, in various embodiments, be differentially encoded. In other embodiments, different address values may be encoded on address bus input 211 in a time-domain multiplex fashion, and address decoder 203 may be operated at different times to generate row selection signals 206 and column selection signals 207 in accordance with the time-domain multiplexing.

The decoding scheme of row decoder 203 may be implemented in accordance with one of various design styles. In some embodiments, row decoder 203 may employ a dynamic decoder in which a series of circuit nodes are pre-charged to a pre-determined voltage and one of the circuit nodes is selectively discharged dependent on the value encoded on address bus input 211. Address decoder 203 may, in various embodiments, include latches or flip-flops configured to store the values on address bus input 211 prior to the generation of row selection signals 206 and column selection signals 207.

Address comparator 213 is coupled to provide address match signal 214 to timing and control unit 202 in response to the assertion of decoder enable signal 205 and dependent upon the address value encoded on address bus input 211. As will be described in more detail below, address comparator 213 may, in some embodiments, be configured to store an address value from a previous access to memory 200, and compare the stored address value to the address value encoded on address bus input 211. In other embodiments, the function performed by address comparator 213 may be performed external to memory 200 by a processor, such as processor 101 of SoC 100 as illustrated in FIG. 1.

It is noted that the memory illustrated in FIG. 2 is merely an example. In other embodiments, different numbers of memory sub-arrays, and different number of functional blocks are possible and contemplated.

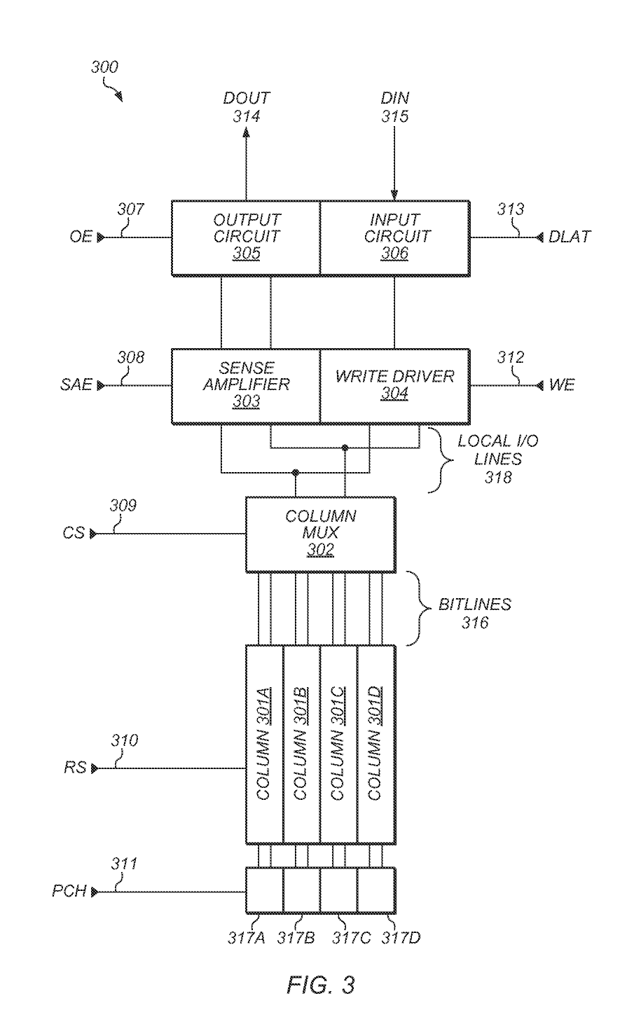

FIG. 3 illustrates an embodiment of a memory sub-array, which may, in some embodiments, correspond to sub-arrays 201a-201c as depicted in FIG. 2. In the illustrated embodiment, sub-array 300 includes a data output 314 denoted as “dout,” a data input 315 denote as “din,” an output enable input 307 denote as “oe,” a sense amplifier enable input 308 denoted as “sae,” a data latch control input 313 denoted as “dlat,” and a write enable input 312 denoted as “we.” The illustrated embodiment also includes one or more column selection input 308 denoted as “cs” one or more row selection inputs 310 denoted as “rs,” and a pre-charge enable input 311 denoted as “pch.”

In the illustrated embodiment, columns 301a, 301b, 301c, and 301d are coupled to the inputs of column multiplexer 302 through bit lines 316. Columns 301a, 301b, 301c, and 301d are also coupled to pre-charge circuits 317a, 317b, 317c, and 317d, respectively. The differentially encoded output of column multiplexer 302 is coupled to the differential inputs of sense amplifier 303, and the differential output of write driver 304 through local I/O lines 318. The output of sense amplifier 303 is coupled to the input of output circuit 305, and the input of write driver 304 is coupled to the output of input circuit 306.

Each column 301 may include one or more data storage cells, whose outputs are coupled to a common pair (a true bit line and a complement bit line) of bit lines 316 (also referred to as data lines). The data storage cells may be configured such that in response to the assertion of one of row selection inputs 310, a respective one of the data storage cells may output its stored data onto the pair of bit lines. In some embodiments, the data storage cells may be static storage cells, while in other embodiments, the data storage cells may be dynamic storage cells, single-bit or multi-bit non-volatile storage cells, or mask programmable read-only storage cells. It is noted that in some embodiments, the data storage cells may transmit data in a single-ended fashion. In such cases, only a single bit line per column may be required.

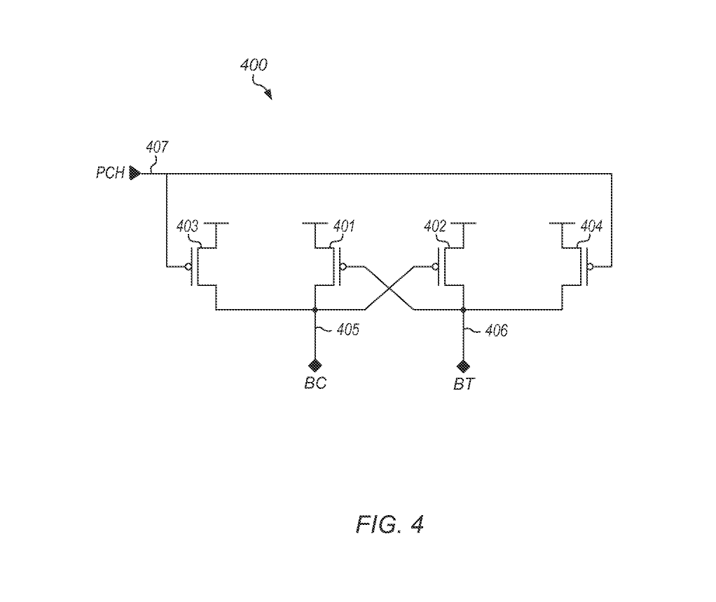

As will be described below in reference to FIG. 4, each of pre-charge circuits 317a, 317b, 317c, and 317d may be configured to charge bit lines 316 to an initialization voltage in response to the assertion of pre-charge enable input 311. In some embodiments, the initialization voltage may be equivalent to the power supply voltage, while, in other embodiments, the initialization voltage may be an analog voltage level such as, half of the power supply voltage, for example.

In the illustrate embodiment, pre-charge circuit 317a, 317b, 317c, and 317d may be operated simultaneously. In other embodiments, each of the aforementioned pre-charge circuits may be operated independently, allowing for a subset of the bit lines 316 to be charged to the initialization voltage.

In some embodiments, column multiplexer 302 may contain one or more pass gates controllable by column selection inputs 308. The input of each pass gate may be coupled to either the true or complement bit line output from one of columns 301a, 301b, 301c, or 301d. The output of each pass gate coupled to a true bit line may be coupled to the true output of column multiplexer 302 in a wired-OR fashion, and the output of each pass gate coupled to a complement bit line may be coupled to the complement output of column multiplexer 302 in a wired-OR fashion. In other embodiments, column multiplexer 302 may contain one or more logic gates configured to perform the multiplexer selection function.

It is noted that a pass gate (also referred to as a “transmission gate”) may include an n-channel metal-oxide-semiconductor field-effect transistor (MOSFET) and a p-channel MOSFET connected in parallel. In other embodiments, a single n-channel MOSFET or a single p-channel MOSFET may be used as a pass gate. It is further noted that, in various embodiments, a “transistor” may correspond to one or more transconductance elements such as a junction field-effect transistor (JFET), for example.

Sense amplifier 303 may be configured to amplify the output of column multiplexer 302 according to one of a number of amplification techniques, such as a latched-based technique, for example. The output of sense amplifier 303 may be a digital signal, a single-ended analog signal, or any other suitable signal encoding the data selected by column multiplexer 302. In cases where the data storage cells of column 301a-301d transmit data in a single-ended fashion, sense amplifier 303 may be configured to amplify the single-ended data.

Write driver 304 may be configured to receive data from input circuit 306 and convert the receive data to a differentially encoded format for driving onto one of bit lines 316 selected by column multiplexer 302. In cases where the data storage cells of column 301a-301d receive data in a single-ended fashion, write driver 304 may be configured to drive single-ended data onto the selected bit line. In some embodiments, write driver 304 may include pre-charge circuits configured to initialize local I/O lines 318 to a pre-determined voltage. In some embodiments, the pre-determined voltage may be equivalent to the power supply voltage, while, in other embodiments, the pre-determined voltage may be an analog voltage level such as, half of the power supply voltage, for example.

Input circuit 306 may be configured to store data from data input 315 in response to the assertion of data latch control input 313. In some embodiments, data input 315 may be transmitted from a source in accordance with an interface standard such as low voltage transistor transistor logic (LVTTL) and the like. In such cases, input circuit 306 may include a level translation circuit configured to convert the data received on data input 315 to logic levels and encoding style suitable for use with write driver 304.

Output circuit 305 may be configured to convert the differentially encoded output of sense amplifier 303 into single-ended data prior to output on data output 314 in accordance with any number of interface standards such as, LVTTL, low voltage complementary metal-oxide semiconductor (LVCMOS), low voltage differential signaling (LVDS), and the like. In some embodiments, output enable input 307 may control the impedance of output circuit 305, allowing for a high impedance state such that multiple circuits may be coupled to data output 314 in a wired-OR fashion.

It is noted that the sub-array illustrated in FIG. 3 is merely an example. In other embodiments, different circuit blocks and different arrangement of circuit blocks may be employed.

An embodiment of a pre-charge circuit is illustrated in FIG. 4. In the illustrated embodiment, pre-charge circuit 400 includes a pre-charge control input 407 denoted as “pch,” a complement bit line port 405 denoted as “bc,” and a true bit line port 406 denoted as “bt.”

In pre-charge circuit 400, pre-charge control input controls pull-up devices 403 and 404. Pull-up device 403 is coupled to complement bit line port 405, and pull-up device 404 is coupled to true bit line port 406. Complement bit line port 405 is further coupled to pull-up device 401, which is controlled by true bit line port 406. True bit line port 406 is further coupled to pull-up device 402, which is controlled by complement bit line port 405.

Prior to a read or write operation to a memory, such as memory 200 as illustrated in FIG. 2, pre-charge circuit 400 may be activated to initialize bit lines to a pre-determined value. Pre-charge control input 407 may be set to a logic low level, thereby activating pull-up devices 403 and 404. Once activated, pull-up devices 403 and 404 supply current to complement bit line port 405 and true bit line port 406, respectively, charging the bit line ports to the supply voltage. As the voltages on complement bit line port 405 and true bit line port 406 increase towards the supply voltage, pull-up devices 401 and 402 are deactivated.

When a read or write operation begins, pre-charge control input 407 may be set to a logic high level, thereby deactivating pull-up devices 403 and 404. During a read operation, a selected data storage cell may discharge either the true or complement bit line dependent upon the data stored in the cell. For example, if the data storage cell contains a logical-1, then the complement bit line may discharge. Pre-charge circuit 400 may sense the accompanying decrease in voltage on complement bit line port 405. The reduction in voltage on complement bit line port 405 may begin to activate pull-up device 402, thereby sourcing current to true bit line port 406.

During a write operation, a write driver circuit, such as write driver circuit 304 as illustrated in FIG. 3, may drive a selected true or complement bit line (selected by column multiplexer 302, for example), to a low logic level dependent upon the data to be written. For example, if the data to be written is a logical-0, then the write driver circuit may discharge the selected true bit line. As described above, pre-charge circuit 400 responds to the decrease in voltage on one of the bit lines by activating either pull-up device 401 or 402 dependent upon which bit line discharges.

It is noted that “low” or “low logic level” refers to a voltage at or near ground and that “high” or “high logic level” refers to a voltage level sufficiently large to turn on a n-channel MOSFET and turn off a p-channel MOSFET. In other embodiments, different technology may result in different voltage levels for “low” and “high.”

The pre-charge circuit depicted in FIG. 4 is merely an example. In other embodiments, different types and arrangements of transistors are possible.

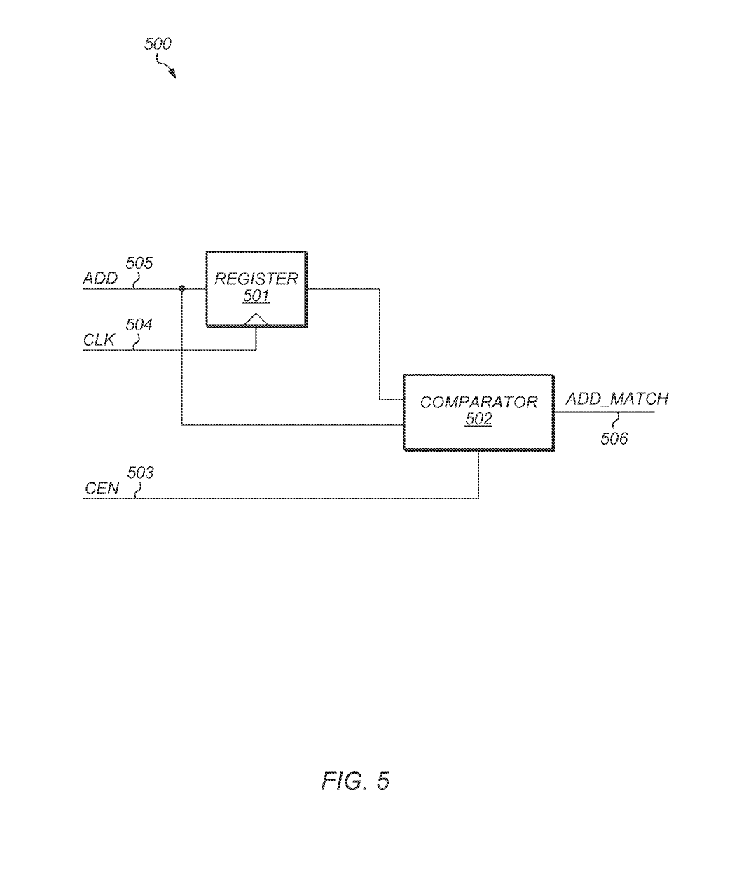

Turning to FIG. 5, an embodiment of an address comparator such as, e.g., address comparator 213 in the embodiment of memory 200 illustrated in FIG. 2, is depicted. The illustrated embodiment includes an address input 505 denoted as “add,” a clock input 504 denoted as “clk,” a compare enable input 503 denoted as “cen,” and an address match output 506 denoted as “add match.”

In the illustrated embodiment, register 501 is coupled to receive and store address data from address input 505. The output of register 501 is coupled to an input of comparator 502. Another input of comparator 502 is coupled to address input 505, and the output of comparator 502 is coupled to address match output 506.

Register 501 may include one or more latches, flip-flops, or other suitable storage circuits, each of which is configured to store one bit of an address value presented on address input 505 in response to clock input 505. The latches and flip-flops may be designed in accordance with one of various design styles. For example, latches and flip-flops may be implemented using either dynamic or static circuits, or a combination thereof. In some embodiments, each storage circuit may include scan cells as part of the implementation of a boundary scan test circuit.

Comparator 502 may be implemented in accordance with one of a number of circuit design styles. For example, comparator 502 may employ static or dynamic exclusive-OR gates, or any other suitable comparison circuit. In some embodiments, comparator 502 may compare all of the bits of the address value presented on address input 505 to the address value stored in register 501. In other embodiments, only a portion of the bits of the address value presented on address input 505, such as the bits involved in decoding a row selection signal, may be compared.

During operation, an address value presented on address input 505 may be stored by register 501 in response to the either the rising or falling edge of clock input 504. During a subsequent operation of the circuit, comparator 502 compares one or more bits of the address value presented on address input 505 against a previously stored address value contained in register 501. When the current address value and the previous address values match, comparator 502 asserts address match 506.

It is noted that the address comparator circuit illustrated in FIG. 5 is merely an example. In other embodiments, different circuit blocks and different configurations of circuit blocks may be possible.

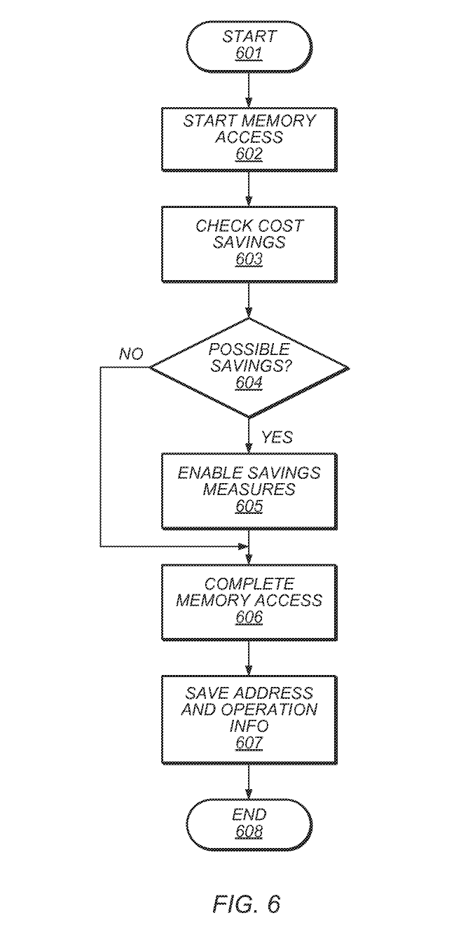

A method for operating a memory device is depicted in the flowchart illustrated in FIG. 6. The method begins in block 601. An access, either a read or write access, to the memory device may then be initiated (block 602). The memory device may then check to see if a cost savings for the access is possible (block 603). The cost savings may be an energy cost, an access time cost, or any other suitable metric of the memory device. In some embodiments, the determination may be made external to the memory device by a processor, controller, or other suitable processing device.

The method is then dependent upon the results of the check of cost savings (block 604). When a cost savings is possible, the memory device may enable savings measures (block 605). The savings measures may, in some embodiments, include the deactivation of circuits included within the memory device, such as, pre-charge circuits, for example. In other embodiments, the savings measures may be enabled by a processor or controller external to the memory device. With the savings measures enabled, the memory device may then complete the access cycle that is in progress (block 606). When a cost savings is not possible, the memory device completes the access cycle that is in progress (block 606).

Once the access to the memory device is complete, address and operation information may be saved (block 607). The operation information may include whether the access was a read access or a write access, or any other suitable information regarding the operation of the memory device. In some embodiments, the address and operation information may be saved within the memory device while, in other embodiments, the address and operation information may be stored external to the memory device in a register file, one or more flip-flops, or any suitable storage circuit.

With the saving of the address and operation information, the method concludes in block 608. It is noted that the method illustrated in FIG. 6 is merely an example. In other embodiments, different operations and different orders of operations are possible.

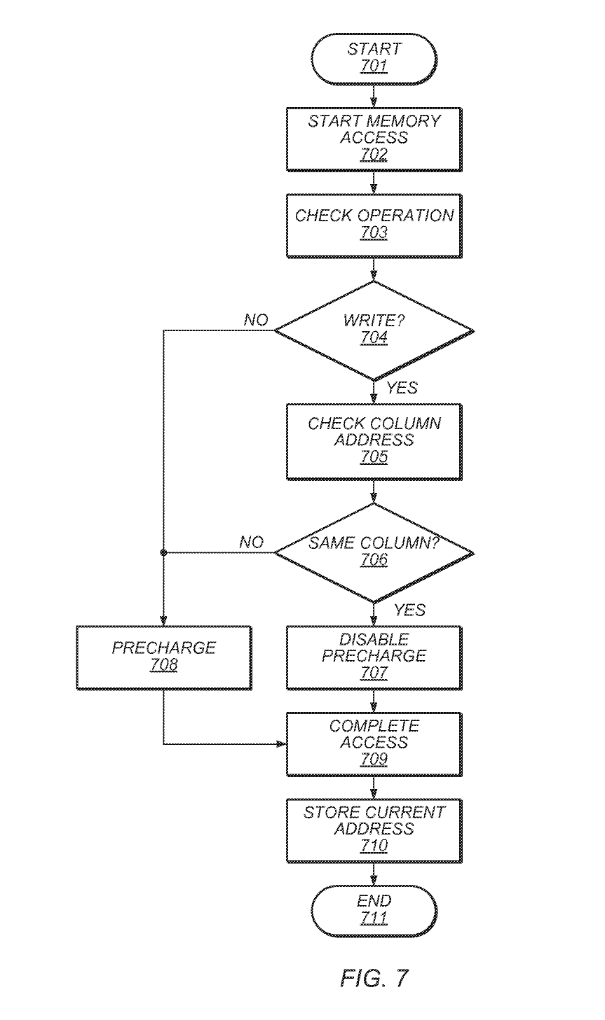

In some embodiments, the cost savings described with respect to FIG. 6 may be possible in cases where memory operations are repeated within a range of addresses in a memory device. Turning to FIG. 7, a flowchart depicting an embodiment of a method for performing repeated operations to a same column of a memory device is illustrated. The method begins in block 701. An access to the memory device may then be started (block 702). An operation such as, e.g., a read operation or a write operation, that the memory device is to perform is then determined (block 703). The method is then dependent upon the operation to be performed (block 704). When the operation to be performed is not a write operation, the array of data storage cells in the memory device is pre-charged (block 708), and the access continues (block 709). The access may be started in response to a clock edge or any other suitable timing or enable signal provided to the memory device. Once the cycle has been completed, the address value at which the operation was performed is saved (block 710) and the method completes (block 711).

When the operation to be performed is a write operation, the column address is then checked (block 705). In some embodiments, the check may include a comparison between the address at which the operation is to be performed and a previously stored address value. The comparison may only compare the bits of the address value used to determine which column is selected. The method then depends on the result of the column check (block 706). When the current column address matches the previously stored column address, the column selected by the current column address is not pre-charged (block 707). In some embodiments, not pre-charging the selected column may result in reduced operating power of the memory device. The method then proceeds as described above starting at block 709.

When the current column address does not match the previously stored column address, the column selected by the current column address is pre-charged (block 708). The method then proceeds, as described above, starting at block 709. It is noted that the method illustrated in FIG. 7 is merely an example. In other embodiments, different operations and different orders of operations are possible.

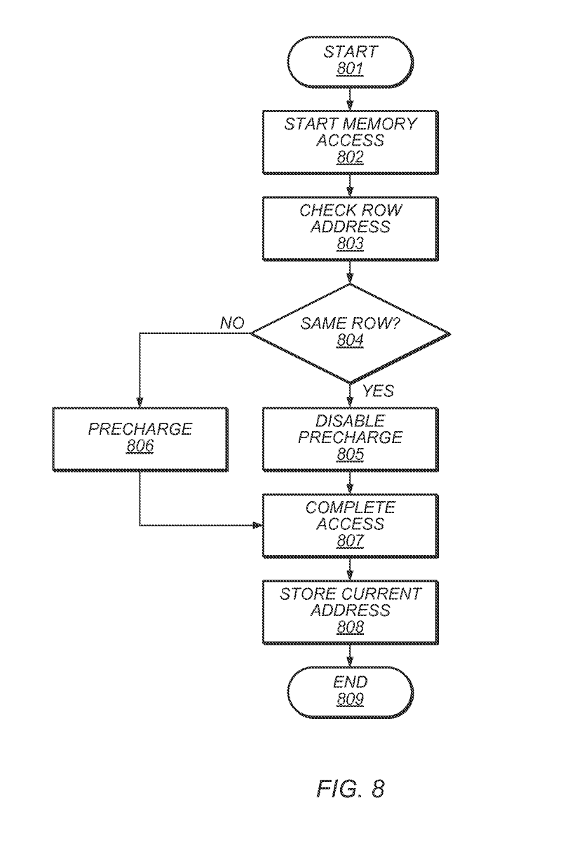

In other embodiments, repeated operations to a same row address may be employed in determining possible cost savings as described above in reference to FIG. 6. Turning to FIG. 8, an embodiment of a method for performing repeated operations to a same row address in a memory device, such as, e.g., memory device 200, is illustrated. Referring collectively to FIG. 2, FIG. 3, and the flowchart depicted in FIG. 8, the method begins in block 801. A memory access is then started (block 802). The start of the memory access may begin in response clock input 209 transitioning to a high logic level. In some embodiments, mode input 210 may be set a logic level necessary to select either a read or write operation, and an address value may be presented on address input 211.

The portion of the address value used in the generation of row selection signals 206 is then compared against a previously stored address value (block 803). The comparison may be performed by address comparator 213 in response to the assertion of decoder enable signal 205. In some embodiments, the previously stored address may be stored in address comparator 213. In other embodiments, the previously stored address may be stored external to the memory device, and the comparison of address values may also be performed external to the memory device. The method then depends on the result of the comparison (block 804).

When the comparison indicates that a different row within sub-arrays 201a-201c is being accessed than a previous access, the sub-arrays are pre-charged (block 806). Timing and control block 202 may generate a pre-charge signal to activate pre-charge circuits (e.g., pre-charge circuits 317a-317d in sub-array 300) in response to address match signal 214 not being asserted. In some embodiments, the activation of the pre-charge circuits may be controlled externally to the memory device by employing pre-charge input signal 212, for example.

Once pre-charge has been completed, the remaining portion of the access to the memory device may be completed (block 807). The remaining portion of the access may include selecting a row and column, sensing data from a selected data storage cell, and any other suitable operations necessary to retrieve from or store data in the memory device. With the completion of the memory access, the current address value is then stored for use in subsequent accesses to the memory device (block 808). The current address value may be stored in address comparator 813. In other embodiments, the current address value may be stored external to the memory device. Once the current address has been stored, the method concludes (block 809).

When the comparison indicates that the row within sub-arrays 201a-201c that is being accessed is the same as a previous access, the sub-arrays are not pre-charged (block 805). Timing and control block 202 may not generate a pre-charge signal to activate pre-charge circuits (e.g., pre-charge circuits 317a-317d in sub-array 300) in response to address match signal 214 being asserted. In some embodiments, the prevention of activation of the pre-charge circuits may be controlled externally to the memory device by employing pre-charge input signal 212, for example, and may result in a power savings for the memory device. The method the proceeds, as described above, from block 807.

It is noted that operations illustrated in FIG. 8 are executed in a sequential fashion. In some embodiments, the operations may occur concurrently or in a different order than the example method illustrated in FIG. 8.

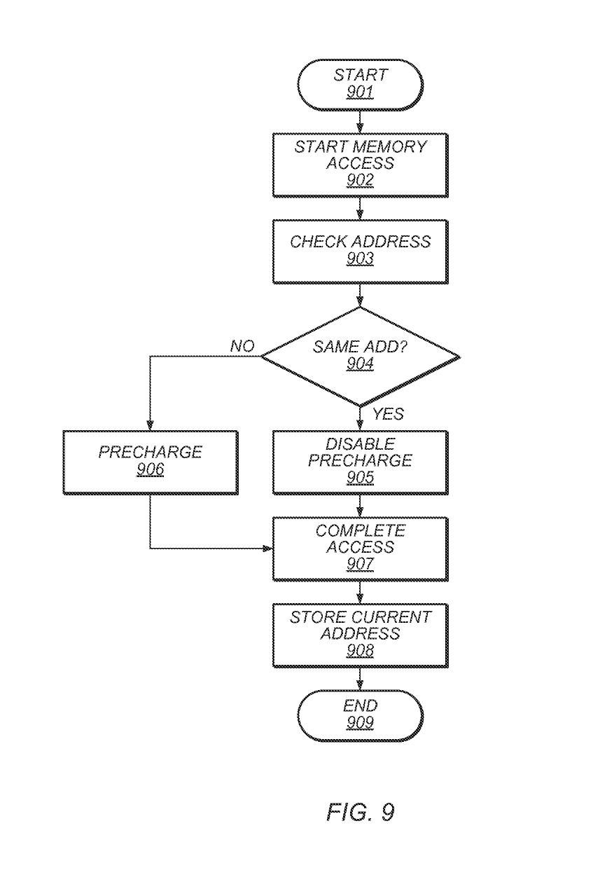

In addition to cost savings when repeatedly performing operations to a same row address or a same column address within a memory device, cost savings may be realized when operations are repeatedly performed to the same address (both row address and column address). A method for performing operations to a same address (both row address and column address) of a memory device is illustrated in FIG. 9. Referring collectively to FIG. 2, FIG. 3, and the flowchart depicted in FIG. 9, the method begins in block 901. A memory access is then started (block 902). The start of the memory access may begin in response clock input 209 transitioning to a high logic level. In some embodiments, mode input 210 may be set a logic level necessary to select either a read or write operation, and an address value may be presented on address input 211.

The current address value may then be compared against a previously stored address value (block 903). The comparison may be performed by address comparator 213 in response to the assertion of decoder enable signal 205. In some embodiments, the previously stored address may be stored in address comparator 213. In other embodiments, the previously stored address may be stored external to the memory device, and the comparison of address values may also be performed external to the memory device. The method then depends on the result of the comparison (block 904).

When the comparison indicates that a different address is being accessed than the previous access, the sub-arrays are pre-charged (block 906). Timing and control block 202 may generate a pre-charge signal to activate pre-charge circuits (e.g., pre-charge circuits 317a-317d in sub-array 300) in response to address match signal 214 not being asserted. In some embodiments, the activation of the pre-charge circuits may be controlled externally to the memory device by employing pre-charge input signal 212, for example.

Once pre-charge has been completed, the remaining portion of the access to the memory device may be completed (block 907). The remaining portion of the access may include selecting a row and column, sensing data from a selected data storage cell, and any other suitable operations necessary to retrieve from or store data in the memory device. With the completion of the memory access, the current address value is then stored for use in subsequent accesses to the memory device (block 908). The current address value may be stored in address comparator 213. In other embodiments, the current address value may be stored external to the memory device. Once the current address has been stored, the method concludes (block 909).

When the comparison indicates that the same address that is being accessed as a previous access, the sub-arrays are not pre-charged (block 905). Timing and control block 202 may not generate a pre-charge signal to activate pre-charge circuits (e.g., pre-charge circuits 317a-317d in sub-array 300) in response to address match signal 214 being asserted. In some embodiments, the prevention of activation of the pre-charge circuits may be controlled externally to the memory device by employing pre-charge input signal 212, for example, and may result in reduced operating power for the memory device. The remaining portion of the memory access is then completed as described in more detail above.

It is noted that the method illustrated in FIG. 9 is merely an example. In other embodiments, different operations are possible and contemplated.

Numerous variations and modifications will become apparent to those skilled in the art once the above disclosure is fully appreciated. It is intended that the following claims be interpreted to embrace all such variations and modifications.

What is claimed is:

1. A memory circuit, comprising:
a plurality of columns, wherein each column comprises:
a plurality of data storage cells wherein each of the data storage cells is coupled to a common data line; and
a pre-charge circuit configured to charge the common data line to a pre-determined voltage level;
an address comparator circuit configured to compare an address value to a previous address value and generate an address match signal dependent upon the comparison; and
a timing and control circuit coupled to the address comparator circuit and configured to disable at least one pre-charge circuit dependent upon the address match signal.

2. The memory circuit of claim 1, wherein the timing and control circuit is further configured to receive a memory mode control signal.

3. The memory circuit of claim 2, wherein the timing and control circuit is further configured to disable at least one pre-charge circuit dependent upon the received memory mode control signal.

4. The memory circuit of claim 1, wherein the pre-determined voltage level comprises a power supply voltage level.

5. The memory circuit of claim 1, wherein the address comparator is further configured to compare the data bits of the address value against the previous address value responsible for selection one of the plurality of columns.

6. The memory circuit of claim 1, wherein the timing and control unit is further configured to receive an external pre-charge control signal.

7. The memory circuit of claim 6, wherein the timing and control unit is further configured to disable at least one pre-charge circuit dependent upon the received external pre-charge control signal.

8. A system, comprising:
one or more memories; and
a processor configured to:
generate a memory address value;
generate a memory mode control signal; and
access at least one of the one or more memories using the memory address value and the memory mode control signal;
wherein each of the one or more memories comprises:
a plurality of columns, wherein each column comprises:
a plurality of data storage cells, wherein each of the data storage cells is coupled to a common data line; and
a pre-charge circuit configured to charge the common data line to a pre-determined voltage level;
an address comparator circuit configured to compare the memory address value to a previous memory address value and generate an output dependent upon the comparison; and
a timing and control circuit coupled to the address comparator circuit and configured to disable the pre-charge circuit of one or more of the plurality of columns dependent upon the output of the address comparator circuit.

9. The system of claim 8, wherein the timing and control circuit is further configured to disable one or more of the plurality of pre-charge circuits dependent upon the memory mode control signal.

10. The system of claim 8, wherein the address comparator comprises a register configured to store the previous memory address value.

11. The system of claim 8, wherein the address comparator is further configured to compare the data bits of the memory address value against the previous memory address value responsible for selection of one of the plurality of columns.

12. The system of claim 8, wherein the address comparator comprises one or more exclusive-OR logic gates.

13. The system of claim 8, wherein the processor is further configured to generate a pre-charge control signal.

14. The system of claim 13, wherein the pre-charge circuit included in the plurality of columns is further configured to charge the common data line dependent upon the generated pre-charge control signal.

15. A method, comprising:
starting an access to a memory device;
determining possible energy cost savings for the access;
enabling energy cost savings measures dependent upon the determination;
storing operational parameters to the memory access.

16. The method of claim 15, wherein determining possible energy cost savings comprises comparing a current address value to a previous address value.

17. The method of claim 16, wherein determining possible energy cost savings further comprises comparing a current operation mode with a previous operation mode.

18. The method of claim 15, wherein enabling energy cost savings comprises de-activating at least one of a plurality of pre-charge circuits included in the memory device.

19. The method of claim 15, wherein storing operation parameters comprises storing a current address value.

20. The method of claim 15, further comprising completing the access to the memory device.
